(19) United States
(12) Patent Application Publication
(10) Pub. No.: US 2023/0017562 A1
(43) Pub. Date: Jan. 19, 2023

(54) SEMICONDUCTOR LASER MODULE

(71) Applicant: Mitsubishi Electric Corporation, Chiyoda-ku, Tokyo (JP)

(72) Inventor: Daisuke MORITA, Tokyo (JP)

(73) Assignee: Mitsubishi Electric Corporation, Chiyoda-ku, Tokyo (JP)

(21) Appl. No.: 17/784,804

(22) PCT Filed: Feb. 24, 2021
(86) PCT No.: PCT/JP2021/006811

§ 371 Date: Jun. 13, 2022

(30) Foreign Application Priority Data
Mar. 5, 2020 (JP) 2020-038255

(51) Int. Cl. H01S 5/024; H01S 5/042; H01S 5/023

(52) U.S. Cl. CPC H01S 5/02423; H01S 5/02469; H01S 5/04256; H01S 5/023

(57) ABSTRACT

A semiconductor laser module includes a semiconductor laser element that outputs a laser beam, a cathode that is for causing a current to flow through the semiconductor laser element, and a heat sink that dissipates heat generated in the semiconductor laser element. The heat sink includes an anode, a first insulating layer located at a position farther away from the semiconductor laser element than the anode, and a water passage portion located at a position farther away from the semiconductor laser element than the first insulating layer. The water passage portion is formed by metal and includes a part of a flow path of water for dissipation of heat generated in the semiconductor laser element.

### FIELD

The present disclosure relates to a semiconductor laser module that outputs a laser beam.

### BACKGROUND

Conventionally, there has been used a laser system including a plurality of semiconductor laser modules that output a laser beam in order to machine a workpiece. In order to increase output of the laser system, it is required to increase output of each of the plurality of semiconductor laser modules. The increase in the output of the semiconductor laser module causes an increase in a temperature of a semiconductor laser element as a heating amount increases. In order to prevent deterioration of initial characteristics related to output of the semiconductor laser element, a semiconductor laser module considering exhaust heat performance has been proposed (see, for example, Patent Literature 1).

Patent Literature 1 discloses a laser device including an anode cooler including a top anode cooler, on which a semiconductor laser element is placed, and a bottom anode cooler. The laser device allows the top anode cooler to be cooled by injecting water to the top anode cooler, in a water passage constituted by the top anode cooler and the bottom anode cooler. When the top anode cooler is cooled, an increase in temperature of the semiconductor laser element is mitigated.

### CITATION LIST

### Patent Literature

Patent Literature 1: Japanese Translation of PCT International Application Laid-open No. 2019-526165

### SUMMARY

### Technical Problem

However, in the technique disclosed in Patent Literature 1, erosion occurs in the top anode cooler due to water injection, and the top anode cooler becomes defective. Further, in the technique disclosed in Patent Literature 1, since a voltage is applied to water in a water passage, electrolytic corrosion occurs in the top anode cooler, and the top anode cooler becomes defective. That is, with the technique disclosed in Patent Literature 1, it is difficult to prolong the life of the semiconductor laser module.

The present disclosure has been made in view of the above, and an object of the present disclosure is to obtain a semiconductor laser module that prevents deterioration of initial characteristics related to output, and prolongs life.

### Solution to Problem

In order to solve the above-described problems and achieve the object, a semiconductor laser module according to the present disclosure includes: a semiconductor laser element that outputs a laser beam, a cathode that is for causing a current to flow through the semiconductor laser element, and a heat sink that dissipates heat generated in the semiconductor laser element. The heat sink includes an anode, a first insulating layer located at a position farther away from the semiconductor laser element than the anode, and a water passage portion located at a position farther away from the semiconductor laser element than the first insulating layer. The water passage portion is formed by metal, and includes a part of a flow path of water for dissipation of the heat described above.

### Advantageous Effects of Invention

The semiconductor laser module according to the present disclosure has an effect of preventing deterioration of initial characteristics related to output and prolonging life.

### BRIEF DESCRIPTION OF DRAWINGS

FIG. 1 is a view schematically illustrating a cross section of a semiconductor laser module according to a first embodiment.

FIG. 2 is a view schematically illustrating a plane of the semiconductor laser module according to the first embodiment.

FIG. 3 is a view schematically illustrating a cross section of a semiconductor laser module according to a second embodiment.

FIG. 4 is a view schematically illustrating a cross section of a semiconductor laser module according to a third embodiment.

FIG. 5 is a view schematically illustrating a cross section of a semiconductor laser module according to a fourth embodiment.

### DESCRIPTION OF EMBODIMENTS

Hereinafter, a semiconductor laser module according to embodiments will be described in detail with reference to the drawings.

### First Embodiment

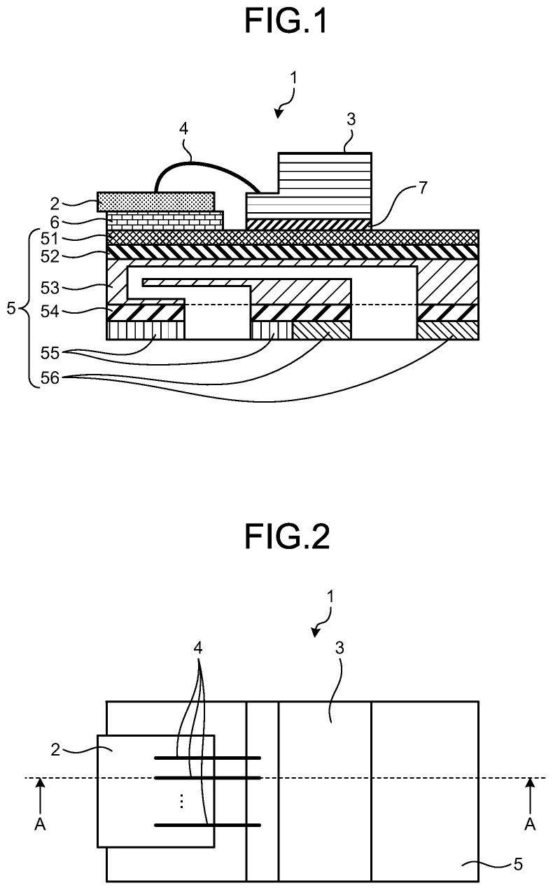

FIG. 1 is a view schematically illustrating a cross section of a semiconductor laser module 1 according to a first embodiment. FIG. 2 is a view schematically illustrating a plane of the semiconductor laser module 1 according to the first embodiment. FIG. 1 is a view taken along a line of allows A-A in FIG. 2. In other words, FIG. 1 is a cross-sectional view taken along line A-A in FIG. 2. The semiconductor laser module 1 includes a semiconductor laser element 2 that outputs a laser beam. For example, a semiconductor mainly contributing to output of the laser beam of the semiconductor laser element 2 is gallium arsenide. For example, oscillation output of the semiconductor laser element 2 is several hundred watts or more. The semiconductor laser module 1 further includes a cathode 3 that is for causing a current to flow through the semiconductor laser element 2. The cathode 3 has conductivity. For example, the cathode 3 is formed by copper.

The semiconductor laser module 1 further includes a conductive wire 4 that connects the semiconductor laser element 2 and the cathode 3. For example, the conductive wire 4 is formed by metal having a relatively small electric resistance and capable of performing bonding at a relatively low temperature. A linear expansion coefficient of the conductive wire 4 is equal to a linear expansion coefficient of the semiconductor laser element 2. For example, the conductive wire 4 is formed by gold or silver.

The semiconductor laser module 1 further includes a heat sink 5 that dissipates heat generated in the semiconductor laser element 2, a conductive submount 6, and a heat dissipation sheet 7 that dissipates heat generated in the semiconductor laser element 2. Details of the heat sink 5 and the conductive submount 6 will be described later. The heat dissipation sheet 7 has electrical insulating properties. For example, a heat conductivity of the heat dissipation sheet 7 is greater than 10 W/K·m, and a thickness of the heat dissipation sheet 7 is 0.3 mm to 0.8 mm. For example, the heat dissipation sheet 7 is formed by silicon.

The heat sink 5 has an anode 51. In the first embodiment, the anode 51 is located on an outermost side close to the semiconductor laser element 2, in the heat sink 5. For example, a heat conductivity of the anode 51 is larger than 300 W/K·m, and a linear expansion coefficient of the anode 51 is larger than a linear expansion coefficient of the semiconductor laser element 2. For example, the anode 51 is formed by copper, and a shape of the anode 51 is a plate shape.

The heat sink 5 further includes a first insulating layer 52 located at a position farther away from the semiconductor laser element 2 than the anode 51. For example, a heat conductivity of the first insulating layer 52 is 150 W/K·m or more and 1000 W/K·m or less, and a linear expansion coefficient of the first insulating layer 52 is smaller than a linear expansion coefficient of the semiconductor laser element 2. For example, the first insulating layer 52 is formed by aluminum nitride or silicon carbide. For example, a shape of the first insulating layer 52 is a plate shape.

The heat sink 5 further includes a water passage portion 53 located at a position farther away from the semiconductor laser element 2 than the first insulating layer 52. The water passage portion 53 has a part of a flow path of water for dissipation of heat generated in the semiconductor laser element 2. The flow path is a non-hatched portion of the heat sink 5 in FIG. 1. The water passage portion 53 is formed by metal. An example of the metal is copper. For example, a heat conductivity of the water passage portion 53 is 300 W/K·m or more and 500 W/K·m or less, and a linear expansion coefficient of the water passage portion 53 is larger than a linear expansion coefficient of the semiconductor laser element 2.

The heat sink 5 further includes a second insulating layer 54 located at a position farther away from the semiconductor laser element 2 than the water passage portion 53. For example, a heat conductivity of the second insulating layer 54 is 150 W/K·m or more and 1000 W/K·m or less, and a linear expansion coefficient of the second insulating layer 54 is smaller than a linear expansion coefficient of the semiconductor laser element 2. For example, the second insulating layer 54 is formed by aluminum nitride or silicon carbide. For example, a shape of the second insulating layer 54 is a plate shape.

In the heat sink 5, as illustrated in FIG. 1, the anode 51, the first insulating layer 52, the water passage portion 53, and the second insulating layer 54 are stacked in this order. The water passage portion 53 is sandwiched between the first insulating layer 52 and the second insulating layer 54. As described above, in the first embodiment, the anode 51 is located on the outermost side close to the semiconductor laser element 2, in the heat sink 5.

The heat sink 5 further includes a water supply portion 55 that is connected to the water passage portion 53 and is for supply of water to the water passage portion 53, and a water discharge portion 56 that is connected to the water passage portion 53 and is for removal of water from the water passage portion 53. Each of the water supply portion 55 and the water discharge portion 56 has a part of a flow path of water. As described above, in FIG. 1, the non-hatched portion is a flow path through which water for dissipation of heat generated in the semiconductor laser element 2 flows.

In FIG. 1, each of the water supply portion 55 and the water discharge portion 56 is located at a position farther away from the semiconductor laser element 2 than a broken line. A part of each of the water supply portion 55 and the water discharge portion 56 is located at a position farther away from the semiconductor laser element 2 than the second insulating layer 54. For example, each of the water supply portion 55 and the water discharge portion 56 is formed by metal. An example of the metal is copper. For example, a heat conductivity of each of the water supply portion 55 and the water discharge portion 56 is 300 W/K·m or more and 500 W/K·m or less, and a linear expansion coefficient of each of the water supply portion 55 and the water discharge portion 56 is larger than a linear expansion coefficient of the semiconductor laser element 2.

Water for dissipation of heat generated by the semiconductor laser element 2 is supplied from a flow path of the water supply portion 55 into the heat sink 5, passes through a flow path of the water passage portion 53, and is discharged from a flow path of the water discharge portion 56 to outside the heat sink 5. In the heat sink 5, water flows through the flow paths of the water supply portion 55, the water passage portion 53, and the water discharge portion 56, and water is not injected in the water passage portion 53.

The conductive submount 6 is formed by a material having a linear expansion coefficient closer to the linear expansion coefficient of the semiconductor laser element 2 than a linear expansion coefficient of a material forming the anode 51 included in the heat sink 5. For example, a heat conductivity of the conductive submount 6 is 150 W/K·m or more and 1000 W/K·m or less. A linear expansion coefficient of the conductive submount 6 is 6 to 7 ppm/K, which is about equal to the linear expansion coefficient of the semiconductor laser element 2. For example, in a case where the semiconductor mainly contributing to output of a laser beam of the semiconductor laser element 2 is gallium arsenide and the anode 51 is formed by copper, the conductive submount 6 is formed by copper tungsten or aluminum nitride. The conductive submount 6 is placed on the anode 51. The semiconductor laser element 2 is placed on the conductive submount 6. The heat dissipation sheet 7 is also placed on the anode 51.

As described above, in the heat sink 5 included in the semiconductor laser module 1 according to the first embodiment, water flows through the flow paths of the water supply portion 55, the water passage portion 53, and the water discharge portion 56. The water flowing through the flow path of the water passage portion 53 dissipates heat generated in the semiconductor laser element 2 via the first insulating layer 52, the anode 51, and the conductive submount 6. That is, the semiconductor laser element 2 is cooled. Therefore, the semiconductor laser module 1 can prevent deterioration of initial characteristics related to output.

In the heat sink 5, water is not injected in the water passage portion 53. Therefore, an occurrence of erosion in the water passage portion 53 is reduced. The anode 51, the first insulating layer 52, the water passage portion 53, and the second insulating layer 54 are stacked in this order in the heat sink 5. That is, the water passage portion 53 is insulated. Therefore, application of a voltage to water flowing through the flow path of the water passage portion 53 is prevented. As a result, a defect due to electrolytic corrosion of the water passage portion 53 is reduced. Therefore, the semiconductor laser module 1 according to the first embodiment can prevent deterioration of initial characteristics related to output and can prolong the life.

The heat sink 5 includes the second insulating layer 54 in addition to the first insulating layer 52. The first insulating layer 52 and the second insulating layer 54 sandwich the water passage portion 53. Therefore, warping of the heat sink 5 including the first insulating layer 52 and the second insulating layer 54 is prevented as compared with a case where the heat sink 5 does not include the second insulating layer 54. That is, a state in which the semiconductor laser element 2 is placed is stabilized as compared with a case where the heat sink 5 does not include the second insulating layer 54. Therefore, the semiconductor laser module 1 according to the first embodiment can prolong the life.

The semiconductor laser module 1 includes the conductive submount 6 having a linear expansion coefficient closer to the linear expansion coefficient of the semiconductor laser element 2 than a linear expansion coefficient of a material forming the anode 51 included in the heat sink 5. The conductive submount 6 is placed on the anode 51. The semiconductor laser element 2 is placed on the conductive submount 6. That is, a stress on the semiconductor laser element 2 is reduced as compared with a case where the semiconductor laser element 2 is directly placed on the anode 51. When the stress on the semiconductor laser element 2 is reduced, a state in which the semiconductor laser element 2 is placed is stabilized. Therefore, the semiconductor laser module 1 according to the first embodiment can prolong the life. In addition, since the linear expansion coefficient of the conductive wire 4 is equal to the linear expansion coefficient of the semiconductor laser element 2, a stress on the semiconductor laser element 2 is reduced, a state in which the semiconductor laser element 2 is placed is stabilized, and thus the life of the semiconductor laser module 1 can be prolonged.

### Second Embodiment

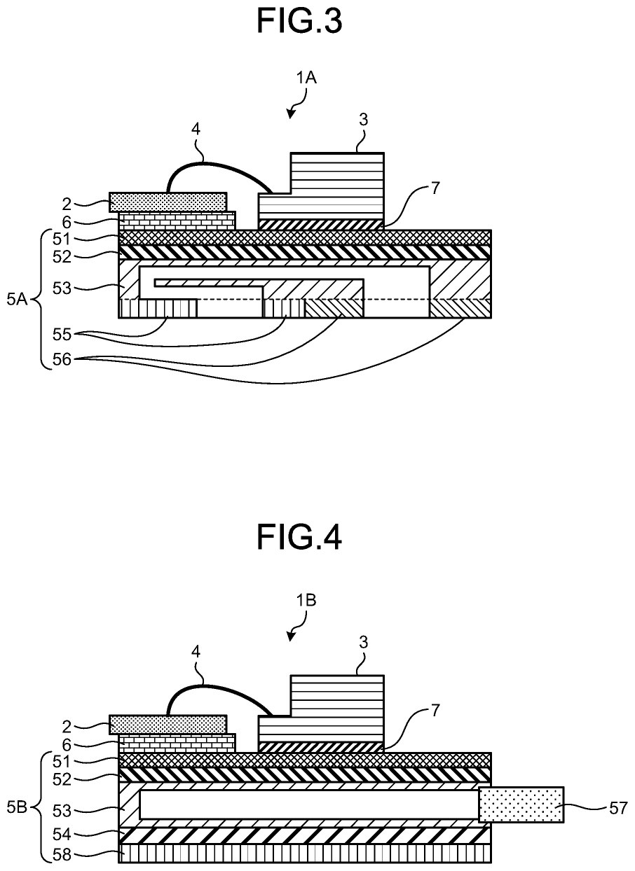

FIG. 3 is a view schematically illustrating a cross section of a semiconductor laser module 1A according to a second embodiment. A plane of the semiconductor laser module 1A is identical to the plane of the semiconductor laser module 1 according to the first embodiment. The semiconductor laser module 1A includes components other than the second insulating layer 54 among all the components included in the semiconductor laser module 1 according to the first embodiment. The semiconductor laser module 1A does not include the second insulating layer 54. Instead of the heat sink 5 of the first embodiment, the semiconductor laser module 1A includes a heat sink 5A including components other than the second insulating layer 54 among the components included in the heat sink 5.

As described in the first embodiment, in the heat sink 5A, water flows through the flow paths of the water supply portion 55, the water passage portion 53, and the water discharge portion 56. The water flowing through the flow path of the water passage portion 53 dissipates heat generated in the semiconductor laser element 2. That is, the semiconductor laser element 2 is cooled. Therefore, the semiconductor laser module 1A can prevent deterioration of initial characteristics related to output. In the heat sink 5A, water is not injected in the water passage portion 53. Therefore, an occurrence of erosion in the water passage portion 53 is reduced. In the heat sink 5A, the water passage portion 53 is insulated. Therefore, a defect due to electrolytic corrosion of the water passage portion 53 is reduced. Therefore, the semiconductor laser module 1A according to the second embodiment can prevent deterioration of initial characteristics related to output and can prolong the life.

The semiconductor laser module 1A also includes the conductive submount 6 having a linear expansion coefficient closer to the linear expansion coefficient of the semiconductor laser element 2 than a linear expansion coefficient of a material forming the anode 51 included in the heat sink 5A. The conductive submount 6 is placed on the anode 51. The semiconductor laser element 2 is placed on the conductive submount 6. That is, a stress on the semiconductor laser element 2 is reduced as compared with a case where the semiconductor laser element 2 is directly placed on the anode 51. When the stress on the semiconductor laser element 2 is reduced, a state in which the semiconductor laser element 2 is placed is stabilized. Therefore, the life of the semiconductor laser module 1A can be prolonged.

### Third Embodiment

FIG. 4 is a view schematically illustrating a cross section of a semiconductor laser module 1B according to a third embodiment. The semiconductor laser module 1B includes components other than the heat sink 5 among all the components included in the semiconductor laser module 1 according to the first embodiment. The semiconductor laser module 1B includes a heat sink 5B including the anode 51, the first insulating layer 52, the water passage portion 53, and the second insulating layer 54, which are included in the heat sink 5.

The heat sink 5B does not include the water supply portion 55 and the water discharge portion 56. The heat sink 5B includes a pipe joint 57 connected to the water passage portion 53. The pipe joint 57 has a function of facilitating attachment, to the heat sink 5B, of a tube for supply of water to the flow path of the water passage portion 53. Water is supplied from outside the semiconductor laser module 1B to the flow path of the water passage portion 53 via the pipe joint 57, and is discharged from the water passage portion 53 to outside the semiconductor laser module 1B via the pipe joint 57. The heat sink 5B further includes a support member 58 located at a position farther away from the semiconductor laser element 2 than the second insulating layer 54. For example, the support member 58 is formed by copper. For example, a shape of the support member 58 is a plate shape. As described above, in the semiconductor laser module 1B, the heat sink 5 is replaced with the heat sink 5B. A plane of the semiconductor laser module 1B is identical to the plane of the semiconductor laser module 1 according to the first embodiment except for the pipe joint 57.

In the heat sink 5B included in the semiconductor laser module 1B according to the third embodiment, water flows through the flow path of the water passage portion 53. The water flowing through the flow path of the water passage portion 53 dissipates heat generated in the semiconductor laser element 2. That is, the semiconductor laser element 2 is cooled. Therefore, the semiconductor laser module 1B can prevent deterioration of initial characteristics related to output. In the heat sink 5B, water is not injected in the water passage portion 53. Therefore, an occurrence of erosion in the water passage portion 53 is reduced. In the heat sink 5B, the water passage portion 53 is insulated. Therefore, a defect due to electrolytic corrosion of the water passage portion 53 is reduced. Therefore, the semiconductor laser module 1B can prevent deterioration of initial characteristics related to output and can prolong the life.

The heat sink 5B includes the second insulating layer 54 in addition to the first insulating layer 52. As compared with a case where the heat sink 5B does not include the second insulating layer 54, warping of the heat sink 5B including the first insulating layer 52 and the second insulating layer 54 is prevented. That is, a state in which the semiconductor laser element 2 is placed is stabilized as compared with a case where the heat sink 5B does not include the second insulating layer 54.

Therefore, the semiconductor laser module 1B according to the third embodiment can prolong the life.

The semiconductor laser module 1B includes the conductive submount 6 having a linear expansion coefficient closer to the linear expansion coefficient of the semiconductor laser element 2 than a linear expansion coefficient of a material forming the anode 51 included in the heat sink 5B. The conductive submount 6 is placed on the anode 51. The semiconductor laser element 2 is placed on the conductive submount 6. That is, a stress on the semiconductor laser element 2 is reduced as compared with a case where the semiconductor laser element 2 is directly placed on the anode 51. When the stress on the semiconductor laser element 2 is reduced, a state in which the semiconductor laser element 2 is placed is stabilized. Therefore, the semiconductor laser module 1B according to the third embodiment can prolong the life.

The semiconductor laser module 1B includes the pipe joint 57. The pipe joint 57 has a function of facilitating attachment, to the heat sink 5B, of a tube for supply of water to the flow path of the water passage portion 53. Therefore, the semiconductor laser module 1B can cause a user to relatively easily supply water to the flow path of the water passage portion 53 by attaching the tube for supply of water to the pipe joint 57. In other words, in a case of using the semiconductor laser module 1B, the user can relatively easily supply water to the flow path of the water passage portion 53 by using the pipe joint 57.

### Fourth Embodiment

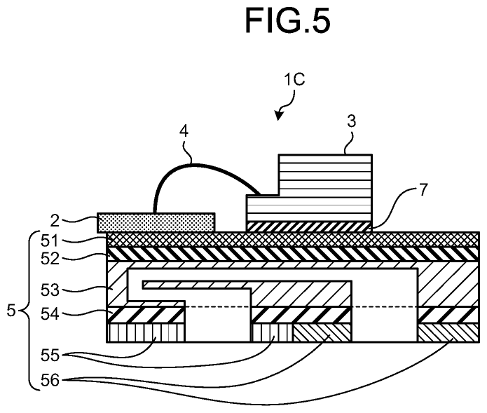

FIG. 5 is a view schematically illustrating a cross section of a semiconductor laser module 1C according to a fourth embodiment. A plane of the semiconductor laser module 1C is identical to the plane of the semiconductor laser module 1 according to the first embodiment. The semiconductor laser module 1C includes components other than the conductive submount 6 among all the components included in the semiconductor laser module 1 according to the first embodiment. Since the semiconductor laser module 1C does not include the conductive submount 6, a cost of the semiconductor laser module 1C is to be lower than a cost of the semiconductor laser module 1.

In the heat sink 5 included in the semiconductor laser module 1C according to the fourth embodiment, water flows through the flow path of the water passage portion 53. The water flowing through the flow path of the water passage portion 53 dissipates heat generated in the semiconductor laser element 2. That is, the semiconductor laser element 2 is cooled. Therefore, the semiconductor laser module 1C can prevent deterioration of initial characteristics related to output. In the heat sink 5, water is not injected in the water passage portion 53. Therefore, an occurrence of erosion in the water passage portion 53 is reduced. In the heat sink 5, the water passage portion 53 is insulated. Therefore, a defect due to electrolytic corrosion of the water passage portion 53 is reduced. Therefore, the semiconductor laser module 1C can prevent deterioration of initial characteristics related to output and can prolong the life. Note that, since the semiconductor laser module 1C does not include the conductive submount 6, the semiconductor laser module 1C can efficiently remove heat generated in the semiconductor laser element 2 as compared with the semiconductor laser module 1 according to the first embodiment including the conductive submount 6.

The heat sink 5 includes the second insulating layer 54 in addition to the first insulating layer 52. As compared with a case where the heat sink 5 does not include the second insulating layer 54, warping of the heat sink 5 including the first insulating layer 52 and the second insulating layer 54 is prevented. That is, a state in which the semiconductor laser element 2 is placed is stabilized as compared with a case where the heat sink 5 does not include the second insulating layer 54.

Therefore, the semiconductor laser module 1C according to the fourth embodiment can prolong the life.

The configurations described in the above embodiments are examples and can be combined with another known technique, the embodiments can be combined with each other, and a part of the configuration can be omitted or modified without departing from the gist.

### REFERENCE SIGNS LIST

1, 1A, 1B, 1C semiconductor laser module; 2 semiconductor laser element; 3 cathode; 4 conductive wire; 5, 5A, 5B heat sink; 6 conductive submount; 7 heat dissipation sheet; 51 anode; 52 first insulating layer; water passage portion; 54 second insulating layer; 55 water supply portion; 56 water discharge portion; 57 pipe joint; 58 support member.

1. A semiconductor laser module comprising:
a semiconductor laser element to output a laser beam;
a cathode to cause a current to flow through the semiconductor laser element; and
a heat sink to dissipate heat generated by the semiconductor laser element, wherein the heat sink includes:
an anode;
a first insulating layer located at a position farther away from the semiconductor laser element than the anode; and
a water passage portion that is located at a position farther away from the semiconductor laser element than the first insulating layer, is formed by metal, and includes a part of a flow path of water for dissipation of the heat, and
the first insulating layer electrically insulates the water passage portion from the anode.

2. The semiconductor laser module according to claim 1, wherein
the heat sink further includes a second insulating layer located at a position farther away from the semiconductor laser element than the water passage portion.

3. The semiconductor laser module according to claim 1, further comprising:
a conductive submount formed by a material having a linear expansion coefficient closer to a linear expansion coefficient of the semiconductor laser element than a linear expansion coefficient of a material forming the anode, wherein
the anode is located on an outermost side close to the semiconductor laser element, in the heat sink,
the conductive submount is placed on the anode, and
the semiconductor laser element is placed on the conductive submount.

4. The semiconductor laser module according to claim 1, wherein
the heat sink further includes:
a water supply portion that is connected to the water passage portion and is to supply water to the water passage portion; and
a water discharge portion that is connected to the water passage portion and is to remove water from the water passage portion.

5. The semiconductor laser module according to claim 1, wherein
the heat sink further includes a pipe joint connected to the water passage portion.

6. The semiconductor laser module according to claim 2, further comprising:
a conductive submount formed by a material having a linear expansion coefficient closer to a linear expansion coefficient of the semiconductor laser element than a linear expansion coefficient of a material forming the anode, wherein
the anode is located on an outermost side close to the semiconductor laser element, in the heat sink,
the conductive submount is placed on the anode, and
the semiconductor laser element is placed on the conductive submount.

7. The semiconductor laser module according to claim 2, wherein
the heat sink further includes:
a water supply portion that is connected to the water passage portion and is to supply water to the water passage portion; and
a water discharge portion that is connected to the water passage portion and is to remove water from the water passage portion.

8. The semiconductor laser module according to claim 3, wherein
the heat sink further includes:
a water supply portion that is connected to the water passage portion and is to supply water to the water passage portion; and
a water discharge portion that is connected to the water passage portion and is to remove water from the water passage portion.

9. The semiconductor laser module according to claim 6, wherein
the heat sink further includes:
a water supply portion that is connected to the water passage portion and is to supply water to the water passage portion; and
a water discharge portion that is connected to the water passage portion and is to remove water from the water passage portion.

10. The semiconductor laser module according to claim 2, wherein
the heat sink further includes a pipe joint connected to the water passage portion.

11. The semiconductor laser module according to claim 3, wherein
the heat sink further includes a pipe joint connected to the water passage portion.

12. The semiconductor laser module according to claim 6, wherein
the heat sink further includes a pipe joint connected to the water passage portion.
